(19) United States
(12) Patent Application Publication
(10) Pub. No.: US 2013/0298979 A1
(43) Pub. Date: Nov. 14, 2013

(54) SEMICONDUCTOR COMPONENTS AND PROCESS FOR THE PRODUCTION THEREOF

(71) Applicant: Wolfgang Schade, Goslar (DE)

(72) Inventor: Wolfgang Schade, Goslar (DE)

(21) Appl. No.: 13/989,634

(22) PCT Filed: Nov. 22, 2011
(86) PCT No.: PCT/EP2011/070706

§ 371 Date: Jul. 29, 2013

(30) Foreign Application Priority Data
Nov. 24, 2010 (DE) 10 2010 061 831.4

(51) Int. Cl. H01L 31/0687; H01L 31/18

(52) U.S. Cl. CPC H01L 31/0687; H01L 31/18
USPC 136/255; 438/98; 438/57

(57) ABSTRACT

A method for producing a light-absorbing semiconductor component, wherein at least one partial area of a semiconductor substrate is irradiated with a plurality of laser pulses having a predefinable length, wherein the pulse shape of the laser pulses is adapted to at least one predefinable desired shape by modulation of the amplitude and/or of the polarization. A semiconductor component for converting electromagnetic radiation into electrical energy, includes a crystalline semiconductor substrate having a first and an opposite second side, wherein a dopant is introduced at least in a partial volume of the semiconductor substrate which adjoins the first side, such that a first pn junction is formed between the partial volume and the substrate, wherein at least one first partial area of the second side is provided with a dopant and a surface modification, such that a second pn junction is formed.

### BACKGROUND

The invention relates to a method for producing a light-absorbing semiconductor component, wherein at least one partial area of a semiconductor substrate is irradiated with a plurality of laser pulses having a predefinable length. Furthermore, the invention relates to a semiconductor component for converting electromagnetic radiation into electrical energy, said semiconductor component comprising a crystalline semiconductor substrate having a first side and an opposite second side, wherein a dopant is introduced at least in a partial volume of the semiconductor substrate which adjoins the first side, such that a first pn junction is formed between the partial volume and the semiconductor substrate. Semiconductor components of the type mentioned in the introduction can be used as photovoltaic cells for supplying energy or as a photodetector for detecting electromagnetic radiation.

A method of the type mentioned in the introduction is known from WO 2006/086014 A2. In accordance with this known method, the surface of a semiconductor substrate is intended to be irradiated with short laser pulses having a duration of 50 fs to 500 fs in the presence of a sulfur-comprising compound. As a result of the nonlinear excitation of the semiconductor substrate by the laser pulses, the surface of the semiconductor substrate is partly remelted and partly converted into a gaseous state. A surface roughness and a polycrystalline or amorphous phase arises as a result. In addition, sulfur as dopant is introduced into the semiconductor substrate. A semiconductor substrate treated in accordance with this known method exhibits—in comparison with untreated silicon—increased light absorption for wavelengths below the band gap energy. In this case, the efficiency of the energy conversion of optical energy into electrical energy is approximately 2.4%.

Proceeding from this known method, it is an object of the invention to improve the efficiency of a photovoltaic cell of the type mentioned in the introduction. Furthermore, it is an object of the invention to provide a more efficient solar cell or a more sensitive photodetector.

### SUMMARY

It has been realized that the pulse shape of the laser pulses, which can be influenced by modulation of the amplitude and/or of the polarization, has effects on the surface structure, the polycrystalline or amorphous material phase that arises, the concentration of the dopants and/or the electrical activity thereof. In this way, through the choice of the pulse shape, the electrical properties, the surface structure and/or the material composition can be influenced within wide limits.

According to the invention, the surface structuring and/or the formation of specific, predefinable phases at the surface is effected using laser pulses having a duration of a few femtoseconds. During the irradiation of the surface of the semiconductor substrate, electrons of the solid are excited, wherein a supersaturated electron gas arises as a result of the high peak pulse powers. In this case, the semiconductor substrate is locally ionized. Finally, the energy of the electron gas is released to the crystal lattice, which leads to the ablation or evaporation of part of the material. The evaporated mass forms a particle stream that propagates with velocities of up to 10³ m·s⁻¹. Within the particle stream, a recoil shockwave arises as a result of the change in density within the gas phase. This shockwave likewise propagates in a direction facing away from the surface of the semiconductor substrate, but at a greater velocity than the particle stream. Therefore, the shockwave is reflected at the interface between the particle stream and the surrounding atmosphere. When the shockwave impinges anew on the surface of the semiconductor substrate, it couples into the liquid surface layer. This results in changes in density in the surface layer, which, upon the cooling of the liquid layer, leads to the formation of polycrystalline and/or amorphous material at the surface.

It has been realized that the surface already solidifies after approximately 500 ps, with the result that this process begins again anew for every incident laser pulse. The invention now proposes adapting the pulse shape of the laser pulses to a predefinable desired shape such that, within a laser pulse, energy is deposited in a plurality of doses directly successively before the surface has completely solidified again. By this means, it is possible to generate a plurality of internal shockwaves with fixedly defined temporal dynamics, such that the formation of the polycrystalline surface layer can be deliberately manipulated or prevented. In this way, the method according to the invention gives rise to larger crystallites having smaller surface area/volume ratios, with the result that the number of recombination centers is reduced. The generated photocurrent and ultimately the efficiency of a solar cell or the sensitivity of a photodetector is increased as a result.

A light-absorbing semiconductor component within the meaning of the present invention is designed to absorb photons and to bring about charge separation in the semiconductor material. In some embodiments of the invention, the non-equilibrium charge carriers generated in this way can be provided as electric current or electric voltage at connection elements of the component.

Some embodiments of the invention can provide for the semiconductor substrate to be exposed to a sulfur-comprising compound while at least one laser pulse impinges on the surface of the substrate. In this case, the sulfur-comprising compound can be dissociated by the impinging laser radiation, with the result that sulfur atoms are incorporated into a layer of the semiconductor substrate near the surface. In some embodiments of the invention, an n-type doping can be produced in this way, with the result that a pn junction can form at the irradiated surface of a p-doped semiconductor substrate. In some embodiments of the invention, the doping can form a multiplicity of electronic states within the band gap, with the result that an intermediate band of electronic states is formed within the band gap of the semiconductor material. The absorption of photons having an energy lower than the band gap energy of the semiconductor substrate can thereby be made possible or at least improved.

In some embodiments of the invention, the predefinable length of a laser pulse can be approximately 10 fs to approximately 1 ns. In this case, within the meaning of the present description, the length of the laser pulses denotes the total length of a pulse, wherein individual pulses can have a temporal spacing of 10 μs to 100 ns. This should be differentiated from the substructure of the amplitude and/or of the phase within a pulse, which can vary on a considerably shorter timescale, for example within 0.1 fs-1.0 fs or within 1 fs-10 fs.

In some embodiments of the invention, the repetition rate can be between 1 kHz and 10 MHz. In this case, the repetition rate describes the temporal spacing of two laser pulses. By contrast, the substructure of an individual pulse can vary with a frequency of a few THz (10¹² Hz). The chosen values firstly ensure that the surface of the semiconductor substrate fully relaxes, i.e. returns to a thermodynamically stable state, after the impingement of an individual laser pulse. By contrast, individual amplitude maxima of the substructure of a laser pulse can couple to the bound electrons and/or the lattice of the semiconductor substrate in an excited state, thus enabling the coherent control of the quantum mechanical system formed by the semiconductor substrate. This allows the influencing of the surface structure, of the polycrystalline or amorphous material phase that arises, of the concentration of the dopants and/or of the electrical activity thereof through the choice of the pulse shape of the laser pulses.

In some embodiments of the invention, the production of the light-absorbing semiconductor component can ensue by irradiation with a single, predefinable pulse shape. In other embodiments of the invention, the method for producing a light-absorbing semiconductor component can be subdivided into a plurality of production steps, wherein different pulse shape of the laser pulses are used in at least two production steps. This makes it possible, for example, to effect doping by means of impurity atoms with a first pulse shape and to create a predefinable surface structure by means of a second pulse shape, which differs from the first pulse shape. In this way, an optimized result can be obtained in each method step.

In some embodiments of the invention, the amplitude of an individual laser pulse can be modulated such that said amplitude has three maxima, wherein at least one maximum has a first amplitude and at least one maximum has a second amplitude, which differs from the first amplitude. In some embodiments of the invention, the amplitude between the maxima for a time period of less than 5 fs can fall to a value of less than 15% of the first and/or of the second amplitude. Such a method implementation enables material removal from an excited state of the electrons of the semiconductor substrate that are near the surface. Furthermore, the method implementation described can have the effect that a liquefied surface layer of the semiconductor substrate is brought to a favorable atomic arrangement by the electric field of the laser pulse before it recrystallizes or solidifies. In this way, in some embodiments of the invention, a polycrystalline surface layer can arise which has larger crystallites having a smaller surface area/volume ratio. In some embodiments of the invention, it is also possible to prevent a polycrystalline surface layer from arising. Finally, in some embodiments of the invention, the surface texture of the semiconductor substrate can be influenced by the choice of the desired shape of the laser pulses.

In some embodiments of the invention, in a subsequent method step, at least one partial area of the semiconductor substrate can be provided with a contact layer. The contact layer can comprise a metal or an alloy. In some embodiments of the invention, the contact layer can have a multilayered construction and be composed of a plurality of thin individual layers.

In some embodiments of the invention, the contact layer on the semiconductor substrate can form an ohmic contact. In this way, charge carriers generated during operation in the semiconductor component can be separated by application of an electric voltage and can be detected or used as electric current. If one partial area of the semiconductor substrate is provided with the contact layer, other area regions or partial areas of the semiconductor substrate can be used for coupling in light during the operation of the semiconductor component. If a semiconductor substrate has area regions that were processed by incidence of a plurality of laser pulses having a predefinable length and pulse shape, and other area regions that were not processed correspondingly, it is possible to provide different contact layers that make contact with either the former or the latter area regions. For this purpose, the different contact layers can have different material compositions and/or different bonding relationships.

In some embodiments of the invention, the semiconductor substrate can be subjected to heat treatment after the irradiation with a plurality of laser pulses. As a result, in some embodiments of the invention, defect states of the crystal lattice can anneal and/or dopants can diffuse within the semiconductor substrate and/or dopants can be electronically activated. In some embodiments of the invention, the semiconductor component can have improved electrical properties if the semiconductor substrate was subjected to heat treatment after the irradiation with a plurality of laser pulses.

In some embodiments of the invention, the surface modification obtained by irradiation with a plurality of laser pulses predefinable pulse shape can have a plurality of columnar elevations having a diameter of approximately 0.3 μm to approximately 1 μm and a longitudinal extent in the direction of the surface normal of approximately 1 μm to approximately 5 μm. Columnar elevations of the type mentioned can firstly improve the light absorption, with the result that the quantum efficiency of a semiconductor component according to the invention rises. Moreover, elevations of the type mentioned allow simple contact-connectability by a contact layer, thus securing the adhesion over the lifetime of the semiconductor component.

In some embodiments of the invention, the semiconductor substrate can comprise p-doped silicon or consist thereof and the dopant can be selected from nitrogen and/or phosphorus and/or arsenic and/or sulfur. In this way, by irradiating the surface of the semiconductor component with a plurality of laser pulses having a predefinable desired shape in the presence of a nitrogen-comprising, phosphorus-comprising, sulfur-comprising or arsenic-comprising compound, it is possible to obtain a pn junction if the compound is dissociated by the laser radiation and the dopants are subsequently incorporated into the material of the semiconductor substrate. If the pulse shape of the laser pulses is adapted to the absorption scheme of the compounds used for doping, the dissociation can be effected by coherent control, with the result that the dopant is incorporated in a predefinable manner.

In some embodiments of the invention, the semiconductor component proposed can comprise at least one photovoltaic cell or consist of at least one photovoltaic cell. In this case, the contact layer of the first side of the semiconductor substrate together with a first contact layer on the second side can form a first photovoltaic cell, and the contact layer of the first side together with a second contact layer of the second side can form a second photovoltaic cell, which are monolithically integrated on a semiconductor substrate. In this way, two photovoltaic cells which absorb light having different wavelengths can be realized on a single semiconductor substrate, with the result that the total efficiency of the photovoltaic cell increases. The two photovoltaic cells monolithically integrated on a semiconductor substrate can be contact-connected independently of one another, be connected to one another in a parallel circuit, in order to increase the output current, or be connected to one another in a series circuit, in order to increase the output voltage of the semiconductor component.

### BRIEF DESCRIPTION OF THE DRAWINGS

The invention will be explained in greater detail below with reference to figures without restricting the general concept of the invention. In this case, in the figures:

FIG. 1 shows a first exemplary embodiment of a pulse shape of the laser pulses which can be used for producing a light-absorbing semiconductor component.

FIG. 2 shows a second exemplary embodiment of a pulse shape of the laser pulses which can be used for producing a light-absorbing semiconductor component.

FIG. 3 shows the wavelength dependence of the absorption of a semiconductor component according to the invention, in which different pulse shapes of the laser pulses were used for production.

FIG. 4 shows a cross section through a semiconductor component in accordance with one embodiment of the invention.

FIG. 5 shows the plan view of the underside of a semiconductor component according to the present invention.

FIG. 6 schematically shows the construction of an apparatus for producing a semiconductor component according to the present invention.

FIG. 7 shows a flowchart of the method proposed according to the invention.

FIG. 8 shows the pre- and rear side and the cross section of a solar cell according to the invention and of a known solar cell.

FIG. 9 shows two SEM micrographs of two silicon surfaces that were treated with different laser pulses.

### DESCRIPTION OF PREFERRED EMBODIMENTS

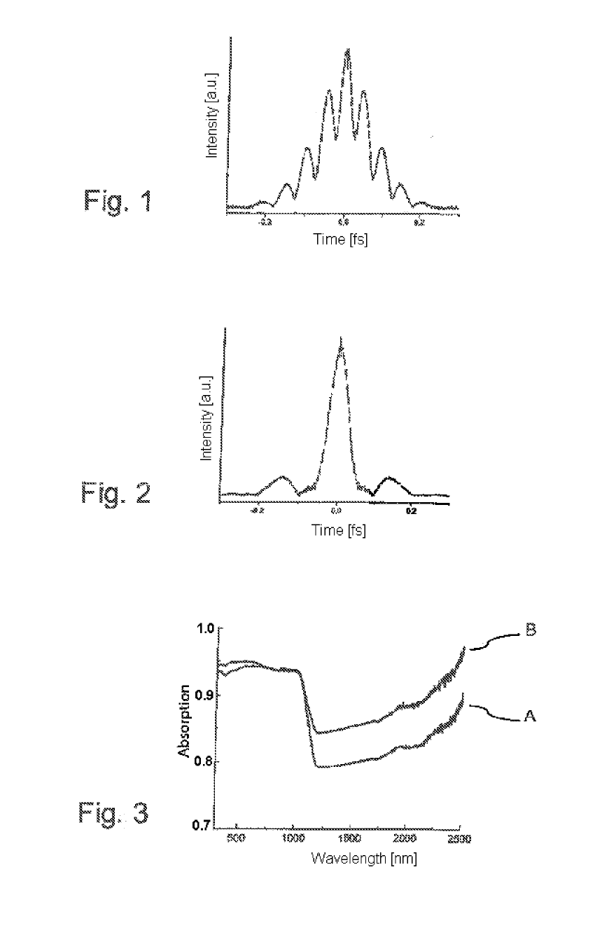

FIG. 1 shows the intensity of emitted laser light on the ordinate and the time in femtoseconds on the abscissa. The illustration shows the profile of the light amplitude of an exemplary pulse shape of a laser pulse which can be used in the proposed method for producing a light-absorbing semiconductor component. The amplitude profile exhibits eight maxima that are emitted approximately equidistantly within 0.4 fs. The absolute value of the amplitude of each maximum is greater than the maximum value of the preceding maximum. In between, the amplitude falls to a likewise rising minimum value.

After reaching the maximum value, the amplitude is returned to the initial value again in an approximately mirror-inverted curve profile. After a pause of predefinable length, the curve profile illustrated in FIG. 1 can be cyclically repeated. The curve profile illustrated in FIG. 1 can be the temporal profile of the amplitude of a laser pulse or an excerpt from a laser pulse which overall has a longer temporal extent.

FIG. 2 shows a second embodiment of a pulse shape according to the present invention. In the exemplary embodiment in accordance with FIG. 2, a curve profile having three maxima is provided, wherein one maximum having a large amplitude is attained in the central region of the curve profile, said maximum being flanked by two maxima having a smaller amplitude. In between, the curve profile falls to a value close to the zero value. In some embodiments of the invention, the minimum value can encompass less than 10% of the adjacent maximum value, less than 5% or less than 1%. In some embodiments of the invention the amplitude can fall to zero at the minimum.

In the same way as shown by way of example for the amplitude and the intensity with reference to FIGS. 1 and 2, the polarization of a laser pulse can also be modulated in a predefinable pattern or a predefinable desired shape.

FIG. 3 shows the absorption capability of a semiconductor component proposed according to the invention. In this case, the semiconductor component comprises a semiconductor substrate, which substantially consists of silicon. Moreover, the semiconductor substrate can comprise customary impurities and/or dopants. The semiconductor substrate was irradiated with a plurality of laser pulses having a predefinable pulse shape at and exposed to a sulfur-comprising compound in the process. This gives rise to at least one partial area having a surface modification, which can comprise an altered surface structure, a polycrystalline or amorphous material phase, and/or a predefinable sulfur concentration.

FIG. 3, then, illustrates the absorption on the ordinate against the wavelength on the abscissa. In this case, curve A shows the profile of the absorption of a semiconductor substrate that was processed using laser pulses whose pulse shape is illustrated in FIG. 1. Curve B shows the profile of the absorption for a semiconductor substrate that was processed using laser pulses having the pulse shape shown in FIG. 2.

It can be discerned from FIG. 3 that, for wavelengths of less than 1100 mm, the absorption is at a value of approximately 0.95. This absorption is attributable to electronic excitations between the valence and a conduction band of the silicon used. If the photon energy falls below the band gap energy, the absorption decreases rapidly. Infrared light can then occur at the surface regions modified by the irradiation with the laser pulses. In this case, the absorption in accordance with curve profile A is always less than the absorption in accordance with curve profile B. The modulation according to the invention of the amplitude and/or of the polymerization of the laser pulses used for material processing can accordingly considerably improve the absorption behavior of a semiconductor component for photon energies below the band gap energy. It is therefore possible to increase the efficiency of a solar cell produced by the method proposed, or the sensitivity of a photodetector produced by the method according to the invention.

FIG. 4 shows a cross section through a monolithic tandem solar cell proposed according to the invention. The solar cell is constructed on a substrate 100. The substrate 100 can comprise silicon or consist thereof. Moreover, the substrate 100 can comprise unavoidable impurities, for example carbon, oxygen or hydrogen. In some embodiments of the invention, the substrate 100 can be p-conductive. For this purpose, the substrate 100 can be doped, for example with gallium, aluminum or boron. The substrate 100 has a first surface 101 and an opposite second surface 102. In some embodiments of the invention, the thickness of the substrate 100 can be approximately 50 μm to approximately 1000 μm.

A dopant can be introduced in a partial volume 110 adjoining the first side 101, said dopant bringing about an n-type conductivity of the partial volume 110. In some embodiments, nitrogen, phosphorus or arsenic can be used as dopant. The partial volume 110 can have a thickness of approximately 2% to approximately 20%, in some embodiments approximately 5% to approximately 10%, of the thickness of the substrate 100.

In this way, a first pn junction 21 forms at the interface between the partial volume 110 and the remaining volume of the substrate 100.

At least one contact layer 210 is arranged on the first side 101. The contact layer 210 can be embodied as a partial coating of the first side 101, with the result that uncovered regions of the first side 101 remain, through which light radiation 30 can penetrate into the volume of the substrate 100 during the operation of the solar cell. In the exemplary embodiment illustrated, the contact layer 210 has a striped or latticed pattern running transversely with respect to the sectional plane. Therefore, the contact layer 210 is illustrated as continuous in FIG. 4. Uncovered partial areas of the first surface are then situated in front of and behind the plane of the drawing.

The opposite second side 102 of the substrate 100 was irradiated with laser pulses having a predefinable duration of between approximately 10 fs and approximately 1 ns, in particular of approximately 50 fs to approximately 500 fs, in the presence of a sulfur-comprising compound, for example SF₆ or H₂S. In this case, the laser pulses have a predefinable pulse shape obtained by modulation of the amplitude and/or of the polarization. Depending on the pulse shape, the intensity, the repetition rate and/or the number of the individual pulses and depending on the concentration of the sulfur-comprising compound, partial volumes 120 in which the chemical composition and/or the phase of the material of the substrate 100 are/is modified arise below the irradiated area regions 240.

By way of example, in the partial volumes 120 a sulfur concentration can be present which brings about the formation of a defect band in the band gap of the semiconductor substrate 100. In some embodiments, a polycrystalline material or an amorphous material can be present in the partial volumes 120. Finally, the surface 240 can be structured, thus resulting in the formation of area regions projecting from the surface 102 in columnar fashion and having a diameter of 0.3 μm to 1 μm and a length of 1 μm to 5 μm. The partial volumes 120 can have a longitudinal extent of 2 μm to 20 μm along the normal vector of the second side 102.

A second pn junction 22 forms at the interface between the partial volume 120 and the interior of the substrate 100.

Furthermore, a second contact layer 220 are situated on the second side 102, said second contact layer at least partly covering the area regions of the second side 102 which are not processed by the laser pulses.

Furthermore, a third contact layer 230 is arranged on the second side 102, said third contact layer at least partly covering the area regions 240 processed by means of the laser radiation.

The contact layers 210, 220 and 230 can comprise a metal or an alloy or consist thereof. In some embodiments of the invention, the contact layers 210, 220 and 230 can have a multilayered construction.

During operation of the semiconductor component in accordance with FIG. 1, sunlight or artificial light 30 impinges on the first side 101 of the substrate 100. The sunlight can penetrate into the substrate 100 through the first side 101. The visible portion of the sunlight 30, that is to say the portion having a wavelength of less than 1100 nm or a photon energy above the band gap energy, is absorbed at the first pn junction 21. The absorption of the light brings about a charge separation, that is to say an excitation of electrons from the valence band into the conduction band. Via the first contact layer 210 and the second contact layer 220, the separated charge carriers can be drawn as current from the semiconductor component.

The infrared portion of the light 30, that is to say light having a wavelength of more than approximately 1100 nm, penetrates through the substrate 100 since the photon energy is lower than the band gap energy. The substrate 100 and the partial volume 110 appear virtually transparent to said infrared light. The infrared light passes to the second pn junction 22, which forms electronic states in the band gap on account of the doping with sulfur atoms and/or the action of the ultrashort laser pulses during production. The effective band gap decreases as a result, and so the infrared light can be absorbed at the second pn junction 22. In this case, free charge carriers once again arise, which can be drawn as current from the semiconductor component via the first contact layer 210 and the third contact layer 230.

In contrast to conventional silicon solar cells, the component proposed according to the invention can thus also utilize the infrared portion of the solar spectrum at least partly for energy production. Said infrared portion amounts to approximately one third of the total incident radiation. The efficiency and the energy yield of the solar cell increase in this way. In contrast to previously known tandem solar cells that absorb the infrared portion of the spectrum in a material having a smaller band gap, such as gallium arsenide, for example, the solar cell proposed according to the invention can be constructed monolithically on a single substrate, thus resulting in a mechanically robust and cost-effective construction. In some embodiments of the invention, the thermal radiation that arises during the operation of a device can be at least partly converted into electrical energy.

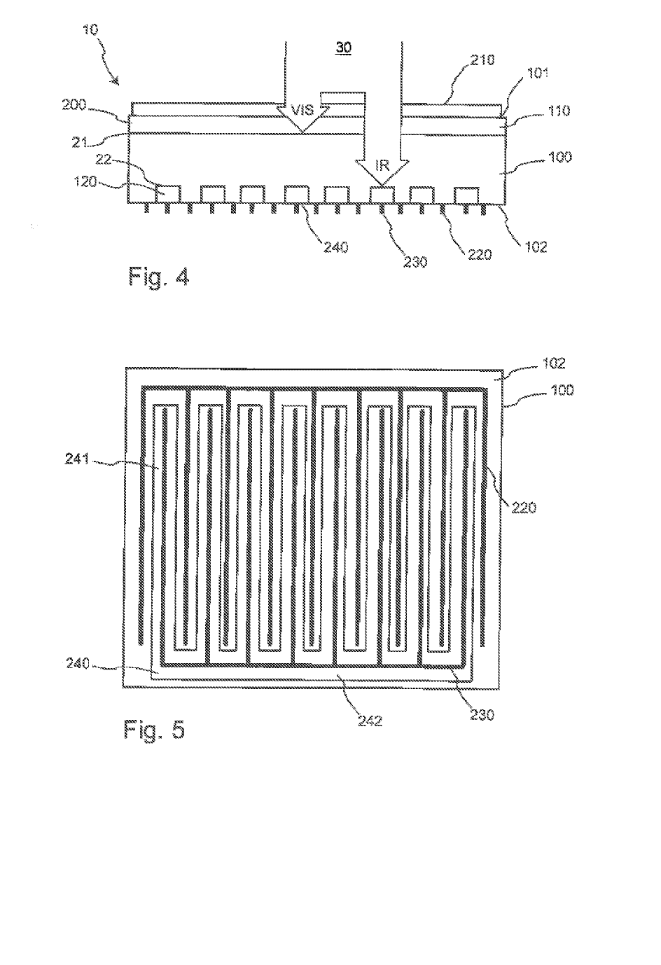

FIG. 5 shows the second side 102 of the substrate 100 in plan view. The area regions 240 can be discerned, which area regions were modified by irradiation with laser pulses having a predefinable pulse shape in order to enable the absorption of infrared light. In the exemplary embodiment illustrated, the area region 240 has a comb-like basic shape, with a plurality of elongate area regions 241 connected to one another by a region 242 running approximately orthogonally.

The third contact layer 230 covers a partial area of the modified area 240, wherein the third contact layer 230 is arranged approximately centrally on the axes of symmetry of the area regions 241 and 242.

The second contact layer 220 also has a comb-like basic shape, wherein the contact layer 220 engages into the interspaces between two adjacent area regions 241. It goes without saying that the interdigital structure illustrated in FIG. 5 should be understood merely by way of example. In other embodiments of the invention, the lateral structuring of the contact layers 220 and 230 and also the basic area of the area 240 modified by the laser pulses can also be chosen differently.

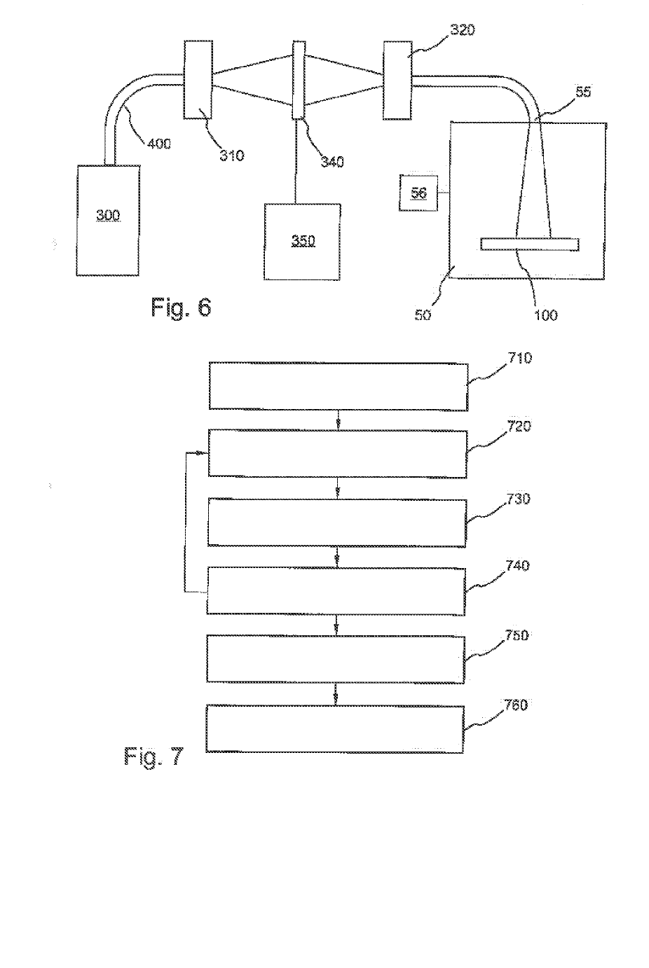

FIG. 6 shows by way of example an apparatus for producing the semiconductor components proposed according to the invention. FIG. 6 illustrates a vacuum chamber 50, which receives the semiconductor substrate 100. The interior of the vacuum chamber 50 can be evacuated by means of a vacuum pump (not illustrated), for example to a pressure of less than 10⁻² mbar, less than 10⁻⁴ mbar, less than 10⁻⁶ mbar or less than 10⁻⁸ mbar.

A gas supply system 56 is connected to the vacuum chamber 50. The gas supply system 56 serves for admitting a gaseous sulfur-comprising compound having a predefinable pressure and/or composition into the chamber 50. By way of example, the gas supply system 56 can admit SF₆ and/or H₂S into the interior of the vacuum chamber 50. The pressure can be between 1200 mbar and 10⁻³ mbar. The pressure and/or the mass flow rate can be kept at predefinable values by corresponding regulating devices.

The vacuum chamber 50 has at least one entrance window through which laser pulses having a predefinable pulse shape can couple into the interior of the vacuum chamber in order subsequently to bring about surface modifications and/or dopings on the semiconductor substrate 100.

The laser pulses 400 are generated by a femtosecond laser 300 known per se. The femtosecond laser can comprise a titanium-sapphire laser, for example. The center frequency of the laser pulses can be adapted to a predefinable desired frequency by frequency multiplication. In some embodiments of the invention, the pulse duration of an individual laser pulse can be between 10 fs and 1 ns. In some embodiments of the invention, the pulse duration can be 10 fs to approximately 50 fs or approximately 50 fs to approximately 500 fs.

In order to generate a desired pulse shape, the laser pulses 400 are spectrally split in a first dispersive element 310. The dispersive element 310 can comprise a grating or a prism, for example. The laser pulses 400 are imaged onto an intermediate focus downstream of the first dispersive element 310, a manipulator 340 being arranged in said intermediate focus. The light is then passed to a second dispersive element 320, the effect of which is the inverse of the effect of the first dispersive element 310.

The manipulator 340 can comprise a spatial light modulator and/or at least one polarizer, for example. In this way, by changing the polarization and/or the amplitude and/or the phase, it is possible to alter the pulse shape or the temporal substructure of the light pulses 400 emitted by the laser light source 300. In this case, it is possible to change the temporal substructure in a simple manner and with only short switching times. It has been recognized according to the invention that the wavelength of the laser is largely unimportant. The temporal substructure of the laser pulses 400 is predominantly crucial for the surface modification of the substrate 100.

The manipulator 340 is driven by a controller 350, which in some embodiments of the invention can also comprise a closed-loop control circuit in order to adapt the temporal substructure of the pulses 400 to a predefinable desired shape. On account of the short switching times, the surface modification of the substrate 100, depending on the desired result, can be effected with a single pulse shape or with a plurality of different pulse shapes that are applied sequentially.

FIG. 7 illustrates the production method according to the invention again in the form of a flowchart. The first method step 710 involves providing a crystalline semiconductor substrate provided with a first side and an opposite second side. A dopant is introduced at least in a partial volume adjoining the first side, with the result that a first pn junction forms in the semiconductor substrate. In some embodiments of the invention, the semiconductor substrate can be provided with a dopant. Moreover, the semiconductor substrate can already be provided with a first contact layer 210 in the first method step 710, which first contact layer carries away the current that later arises during operation from the first side 101.

The substrate 100 is brought into contact with a sulfur-comprising compound having a predefinable composition and concentration. For this purpose, in method step 720 a vacuum chamber can be used, as explained with reference to FIG. 6. In other embodiments of the invention, the sulfur-comprising compound can be applied to the substrate as a liquid film.

Finally, the third method step 730 involves choosing a pulse shape or a temporal substructure with which the surface modification of the substrate 100 is intended to be performed.

Finally, the fourth method step 750 involves irradiating the surface of the substrate 100 at least partly with a predefinable number of pulses and/or a predefinable irradiation duration. This can lead to the incorporation of sulfur atoms into a layer of the substrate 100 that is near the surface. In some embodiments of the invention, alternatively or cumulatively, the crystalline structure of the substrate 100 can be remelted to form a polycrystalline or amorphous structure. Finally, in some embodiments of the invention, a roughening or structuring with columnar elevations can be effected.

In some embodiments of the invention, after irradiation with a first pulse shape and in the presence of a first sulfur-comprising compound, method steps 720, 730 and 740 can be repeated in order to further optimize the electrical and/or mechanical properties of the semiconductor component in this way. In particular, laser pulses can also act on the surface of the substrate without a sulfur-comprising compound coming into contact with the surface. In this case, the surrounding atmosphere is chosen accordingly in method step 720.

After the last action of laser pulses or the last implementation of method step 740, the substrate 100 can be subjected to heat treatment in an optional method step 750. A temperature of between 340 K and 700 K, in particular 400 K to 500 K is suitable for this purpose. By means of the heat treatment, dopants can diffuse within the substrate 100 and/or be electronically activated. In some embodiments, this method step can also be omitted.

In the last method step 760, the contact layers 220 and 230 are applied to the second side 102, with the result that electric current can be carried away from the semiconductor component.

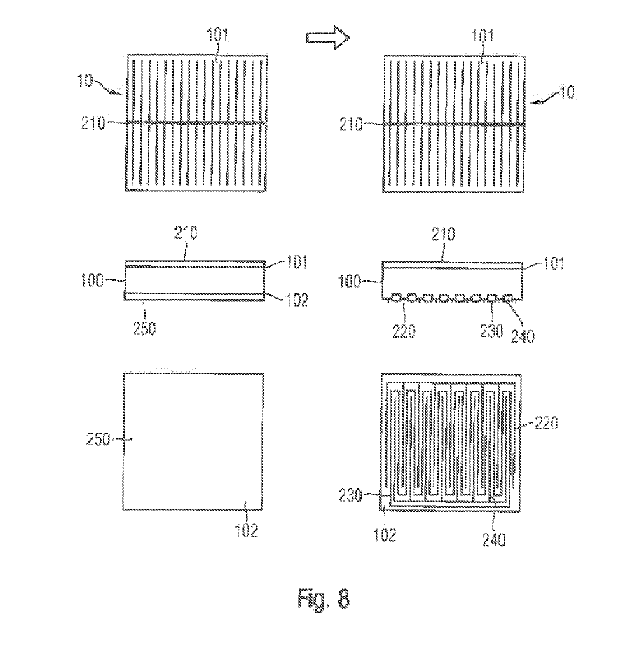

FIG. 8 shows, in the left-hand part of the figure, the front and rear sides and also a cross section through a known solar cell. The right-hand part of FIG. 8 illustrates the front and rear sides and also a cross section through a solar cell according to the invention. FIG. 8 also illustrates how a known solar cell can be structured to form a solar cell according to the invention by means of a small number of method steps.

FIG. 8 shows in the first column the plan view of the first side 101 of the semiconductor component 10. The first side 101 is embodied as a light entrance area through which light can enter into the volume of the semiconductor component 10. Furthermore, the contact layer 210 is arranged on the first side 101. The contact layer 210 is embodied as a partial coating of the first side 101, thereby forming first partial areas, which are covered by the contact layer 210, and second partial areas, which can serve as light entrance areas.

The second side 102 of the known semiconductor component 10 is covered with a contact layer 250 over the whole area. The contact layers 250 and 210 serve to carry away the charge carriers generated by the illumination of the semiconductor component 10 from the volume of the substrate 100 and to make them usable either as a measurement signal of a photodetector or as electrical power of a photovoltaic cell.

This known semiconductor component illustrated in the left-hand part of FIG. 8 has the disadvantage, already explained, that light having a photon energy which is lower than the band gap energy passes from the first side 101 to the second side 102 of the substrate 100 virtually without absorption, without generating free electrical charge carriers in the substrate 100. This portion of the incident light is therefore not available for generating current.

This semiconductor component 10 known per se can now be processed further in accordance with the method illustrated in FIG. 7 to form a semiconductor component according to the invention. For this purpose, in a first method step, it is merely necessary to remove the contact layer 250 on the second side 102 of the substrate 100. The contact layer 250 can be removed by means of a wet- or dry-chemical etching step, by polishing or sputtering. The second side 102 prepared in this way can then be at least partly modified by illumination with correspondingly shaped laser pulses optionally in the presence of a sulfur-comprising compound and can subsequently be provided with contact layers 220 and 230, as already described above in connection with FIG. 7. The cross section of a semiconductor component 10 as described in FIG. 4 and the second side 102 of the semiconductor component 10 as described with reference to FIG. 5 can be formed in this way.

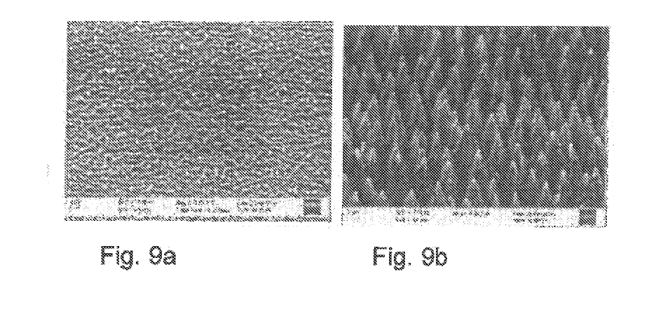

FIG. 9 shows micrographs of area regions 240 of a silicon substrate 100 which were obtained by the action of laser pulses having different pulse shapes. The micrographs in accordance with FIG. 9 were produced by means of a scanning electron microscope. FIGS. 9a and 9b illustrate that the texture of the surface can be influenced within wide limits.

The surface shown in FIG. 9a has a comparatively flat structuring. The contact-connection of the surface by a contact layer 230 can thereby be improved. An improvement in the contact-connection is assumed here if the contact resistance between the substrate 100 and the contact layer 230 is lower and/or the adhesion of the contact layer 230 on the second side 102 of the substrate 100 is increased.

FIG. 9b shows a surface region 240 structured more deeply. In this way, the light absorption is improved in comparison with the surface shown in FIG. 9a, with the result that a predefinable optical intensity can generate a larger quantity of charge in the substrate 100. The method according to the invention thus allows partial areas 240 of the second side 102 of the substrate 100 to be structured in different ways, with the result that each partial area can optimally fulfill the task intended for it.

It goes without saying that the invention is not restricted to the embodiments illustrated in the figures. The above description should therefore not be regarded as restrictive, but rather as explanatory. The following claims should be understood such that a feature mentioned is present in at least one embodiment of the invention. This does not preclude the presence of further features. Insofar as the claims and the above description define “first” and “second” features, this designation serves for differentiating two features of identical type, without defining an order of precedence.

1.-16. (canceled)

17. A method for producing a light-absorbing semiconductor component, comprising the following steps:
providing a substrate having a first side and a second side,
introducing a dopant into at least one partial volume of the semiconductor substrate adjacent to the first side, such that a first pn-junction having a first band gap energy is formed between the partial volume and the semiconductor substrate,
irradiating at least one partial area of the second side of the semiconductor substrate with a plurality of laser pulses having a predefinable length, wherein the pulse shape of the laser pulses is adapted to at least one predefinable shape by modulation of the amplitude and/or of the polarization, such that at least the partial area of the second side is provided with a surface modification, wherein a second pn junction having a second band gap energy is formed, wherein
the second band gap energy is lower than the first band gap energy.

18. The method according to claim 17, wherein the semiconductor substrate is exposed to a sulfur-comprising compound while at least one laser pulse impinges on the surface of the substrate.

19. The method according to claim 17, wherein the predefinable length of the laser pulses amounts from approximately 10 fs to approximately 1 ns.

20. The method according to claim 17, wherein the amplitude of an individual laser pulse is modulated such that the latter has three maxima, wherein at least one maximum has a first amplitude and at least one maximum has a second amplitude.

21. The method according to claim 17, comprising further the step of manufacturing a contact layer on at least one partial area of the semiconductor substrate.

22. The method according to claim 17, wherein the semiconductor substrate is subjected to a heat treatment after the irradiation with a plurality of laser pulses.

23. The method according to claim 17, wherein the amplitude of an individual laser pulse is modulated such that the latter has at least two maxima, wherein the amplitude between the maxima for a time period of less than 5 fs falls to a value of less than 15% of the larger maximum value.

24. A method for producing a light-absorbing semiconductor component, comprising the following steps:
providing a substrate having a first side and a second side,
introducing a dopant into at least one partial volume of the semiconductor substrate adjacent to the first side, such that a first pn-junction having a first band gap energy is formed between the doped partial volume and the semiconductor substrate,
irradiating at least one partial area of the second side of the semiconductor substrate with a plurality of laser pulses having a predefinable length and shape, wherein the shape of the laser pulses is adapted to deposit energy into the semiconductor material by a plurality of doses before the surface has completely solidified again, such that the irradiated partial area of the second side is provided with a surface modification, wherein a second pn-junction having a second band gap energy is formed, wherein
the second band gap energy is lower than the first band gap energy.

25. The method according to claim 24, wherein the semiconductor substrate is exposed to a sulfur-comprising compound while at least one laser pulse impinges on the surface of the substrate.

26. The method according to claim 24, wherein wherein the semiconductor substrate is subjected to a heat treatment after the irradiation with a plurality of laser pulses.

27. The method according to claim 24, wherein the amplitude of each individual laser pulse is modulated such that each pulse has at least two maxima, wherein the amplitude between the maxima for a time period of less than 5 fs falls to a value of less than 15% of the larger maximum value.

28. The method according to claim 24, wherein the predefinable length of a single laser pulse amounts from approximately 10 fs to approximately 1 ns.

29. A semiconductor component for converting electromagnetic radiation into electrical energy, comprising
a crystalline semiconductor substrate having a first side and an opposing second side,
wherein a dopant is introduced at least in a partial volume of the semiconductor substrate being located adjacent to the first side, such that a first pn-junction is formed between the partial volume and the semiconductor substrate,
wherein at least one first partial area of the second side is provided with a dopant and a surface modification, such that a second pn-junction is formed, wherein the first pn-junction is designed to absorb light having a photon energy above the band gap energy of the semiconductor substrate, and
the second pn junction is designed to absorb light having a photon energy below the band gap energy of the semiconductor substrate.

30. The semiconductor component according to claim 29, wherein the surface modification of the first partial area has a plurality of columnar elevations having a diameter of approximately 0.3 μm to approximately 1 μm and/or a longitudinal extent of approximately 1 μm to approximately 5 μm.

31. The semiconductor component according to claim 29, wherein the first irradiated partial area comprises polycrystalline silicon having a grain size of 1 μm to 100 μm.

32. The semiconductor component as claimed in claim 29, wherein the first side comprises at least one contact layer which is formed by means of a partial coating of the first side, and the second side comprises at least two contact layers.

33. The semiconductor component according to claim 32, wherein at least one contact layer being arranged on the second side is adapted to form an electrical contact with the semiconductor substrate and the other contact layer is adapted to form an electrical contact with the first partial area of the second side.

34. The semiconductor component according to claim 29, wherein the semiconductor substrate comprises p-doped silicon or consists thereof and the dopant is selected from N and/or P and/or As and/or S.

35. The semiconductor component according to claim 29, wherein the contact layer on the first side together with the contact layer on the second side forms a first photovoltaic cell and the contact layer of the first side together with the contact layer of the second side forms a second photovoltaic cell, which are monolithically integrated on a semiconductor substrate.

36. The semiconductor component according to claim 35, wherein the first and second photovoltaic cells are interconnected in parallel with one another.
